(19) United States
(12) Patent Application Publication
(10) Pub. No.: US 2009/0147474 A1
(43) Pub. Date: Jun. 11, 2009

(54) APPARATUS FOR PREVENTING REFLUENCE OF AIR IN AN ELECTRONIC DEVICE

(75) Inventor: MING-DER CHOU, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/141,855

(22) Filed: Jun. 18, 2008

(30) Foreign Application Priority Data
Dec. 6, 2007 (CN) 200710202884.9

(51) Int. Cl. H05K 7/20

(52) U.S. Cl. 361/695; 137/512

(57) ABSTRACT

An apparatus including a base plate, and a plurality of diaphragms is provided for preventing refluence of air in an electronic device. Each diaphragm includes a hollow main body, and a plurality of movable petaline portions extending out from an end of the main body. Difference in air pressure may cause the petaline portions of each of the diaphragms to press together to form a closed position to block passage of air through the main bodies of the diaphragms from one direction or move away from each other to form an open position to allow passage of air through the main bodies from an opposite direction.

### BACKGROUND

1. Field of the Invention

Embodiments of the present disclosure relate to an apparatus for inhibiting refluence of air, and more particularly, to an apparatus for inhibiting discharged air from flowing back into an electronic device.

2. Description of related art

An electronic device, such as a computer chassis, usually includes a plurality of cooling apparatuses, such as fans, for dissipating heat produced by electronic components in the chassis. However, when one of the fans malfunctions, hot air blown out by the other fans may pass through the broken fan back into the chassis, which may result in poor cooling efficiency of the electronic device.

In these systems, shutters having adjustable slats may be attached to the fans to inhibit refluence of the hot air into the electronic device. In normal operation, the shutters may be pushed opened to allow hot air to be blown out by the fans. However, when one of the fans breaks down or rotates slowly, the broken fan's shutter may close under the force of gravity, which may inhibit hot air from being blown out by the other fans to flow out of the chassis. Thus, hot air may recirculate throughout the chassis thus reducing the life expectancy of the electronic device.

From the foregoing, it should be appreciated that there is a need for a cooling system that flows out hot air from an electronic device. To this end, there is a need for a cooling system that inhibits hot air from flowing into an electronic device.

### BRIEF DESCRIPTION OF THE DRAWINGS

FIG. 1 is an exploded, isometric view of one embodiment of part of an apparatus for preventing refluence of air in an electronic device;

FIG. 2 is an assembled view of one embodiment of the apparatus of FIG. 1 with a fan; and

FIG. 3 is an isometric view of another embodiment of an apparatus for preventing refluence of air in an electronic device.

### DETAILED DESCRIPTION

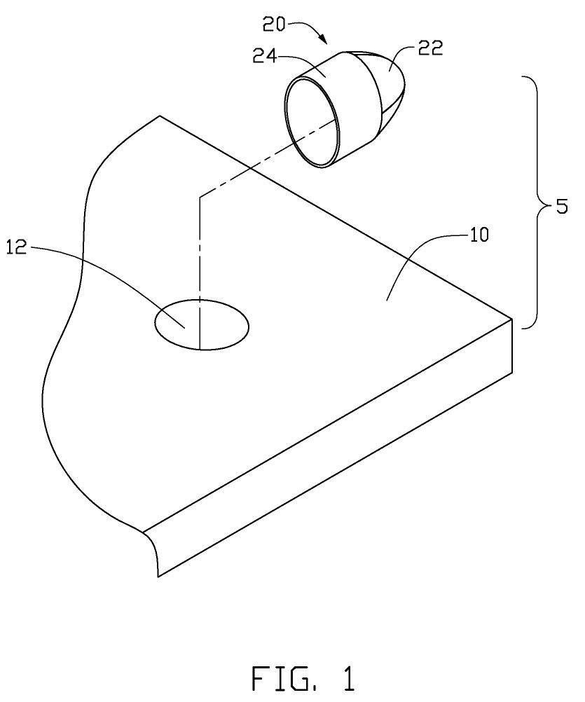

Referring to FIGS. 1 to 3, an apparatus 5 for preventing refluence of air is provided in accordance with one embodiment of the present disclosure. The apparatus 5 may include a base plate 10 defining a plurality of through holes 12 therein, and a plurality of flower-shaped diaphragms 20 corresponding to the through holes 12.

In one embodiment, each diaphragm 20 may include a hollow cylindrical main body 24, and a plurality of movable petaline portions 22 extending out from an end of the main body 24. The main bodyies 24 of the diaphragms 20 engage in the respective through holes 12, and may be fixably engaged to the base plate 10. The petaline portions 22 of the diaphragms 20 are left exposed on a first side of the base plate 10 in one embodiment of the present disclosure. In one embodiment, an area of a cross section of the main body 24 of each of the diaphragms 22 may be substantially equal to a diameter of each of the through holes 12 of the base plate 10.

In one example, when air pressure on a first side of the base plate 10 is greater than on a second side opposite to the first side of the base plate 10, the petaline portions 22 may be pushed towards each other to form a closed position. In one embodiment, the closed positions of the petaline portions 22 may resemble a plurality of closed dome-shaped protrusions. These dome-shaped protrusions may substantially inhibit the flow of air from the first side of the base plate to the second side of the base plate. However, when air pressure on the first side of the base plate 10 is less than that air pressure on the second side of the base plate 10, then the petaline portions 22 may be pushed apart to form an open position. This open position may resemble the petals of an open flower. In one embodiment, there may be at least two petaline portions 22, and the petaline portions 22 may be integrally formed with the main body 24 of the corresponding diaphragm 20. In one embodiment, the petaline portions 22 may be comprised of flexible material, and/or have an elastic member installed therein, to make the petaline portions 22 sensitive to changes in air pressure.

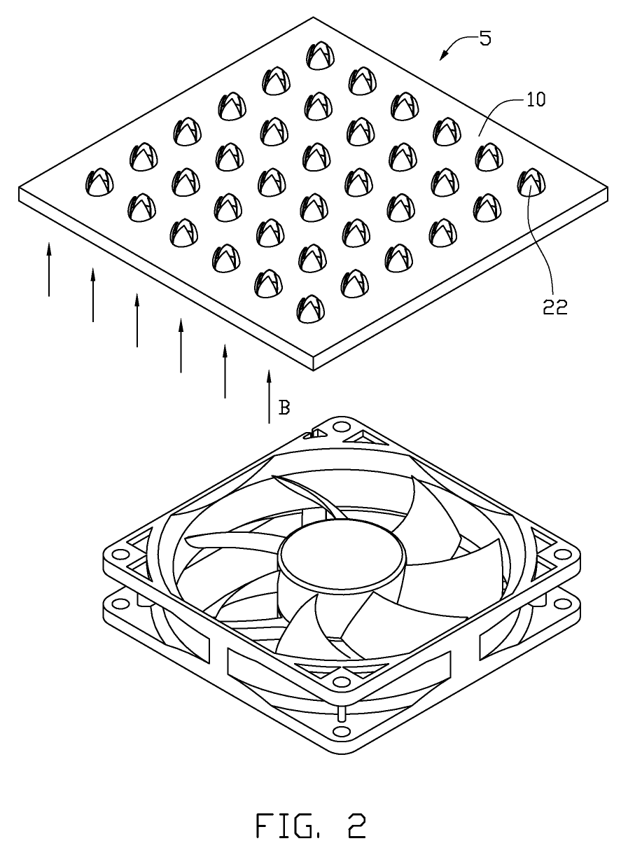

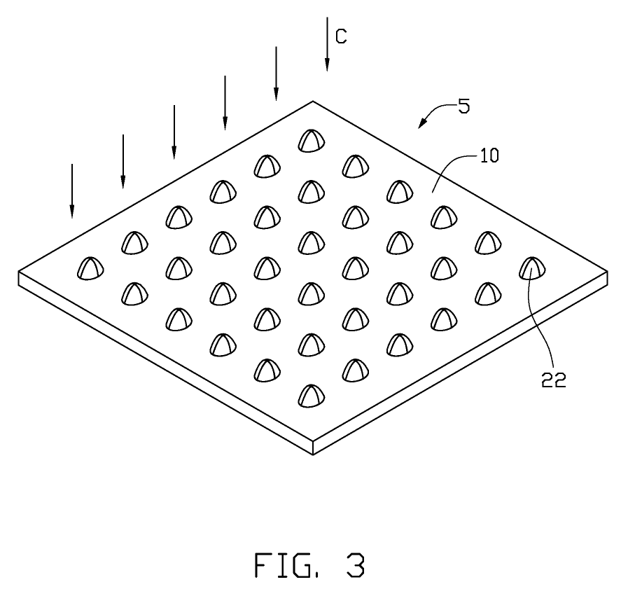

In use, a plurality of the apparatuses 5 may be assembled to a chassis of an electronic device (not shown) having one or more exhaust fans positioned therein. In one embodiment, the apparatuses may be aligned with each of the respective fans. In one embodiment, the second side of each base plate 10 may face the corresponding fan and the interior of the chassis. Hot air in the electronic device may be blown out by the fans in a direction B, as shown in FIG. 2, and flow through the main body 24 of the diaphragm 20. In one embodiment, the petaline portions 22 of the diaphragms 20 may be pushed open by hot air flowing through the main bodies 24 thereof, allowing the hot air to easily flow from the chassis. However, when one or more fans rotate too slowly or stops rotating, outside air may try to flow through the corresponding diaphragms 20 in a direction C (see FIG. 3). In one embodiment, outside air flowing in the direction C may cause the petaline portions 22 to substantially close. Thus, the closed petaline portions 22 may inhibit refluence of any hot air exhausted by the remaining working fans into the chassis.

In one embodiment, the apparatuse 5 may be assembled in a chassis, with the first side of each base plate 10 facing a corresponding exhaust fan, and the second side of each base plate 10 facing an interior of the chassis. In one embodiment, air between the apparatus 5 and the fans may be pushed out by the fans resulting in an air pressure on the first side of the base plate 10 to be less than an air pressure on the second side of the base plate 10. In this particular embodiment, the petaline portions 22 of the diaphragms 20 may be substantially in the open position, thereby allowing hot air to be vented. However, if one or more fans malfunction, then air pressure on the first side of the corresponding base plate 10 may be greater than air pressure on the second side of the corresponding base plate 10 resulting in the petaline portions 22 to be substantially in the closed position, thus preventing refluence of hot air into the chassis. It may be understood that a sufficient difference in air pressure between one side of the base plate relative to another side of the base plate such that it will cause the petalines to open may be referred to as positive pressure. It may be further understood positive pressure may urge a flow of air on one side of the base plate 10 onto another side of the base plate 10. Accordingly, the flow of air may flow through the diaphragms 20 and thus causing the petaline portions 22 to form an open position.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. An apparatus for preventing refluence of air in an electronic device, the apparatus comprising:
a base plate, having a first side and a second side, the base plate defining a plurality of through holes therein; and
a plurality of diaphragms, each diaphragm having a hollow main body, the hollow main body configured to receive a flow of air; and
a plurality of petaline portions extending out from the hollow main body, wherein each of the hollow main bodies are fixably engaged in the through holes;
wherein the petaline portions are biased to form a closed position and configured to move away from each other to form an open position in response to a positive pressure differential sufficient to overcome the bias of the petaline portions; the positive pressure differential comprises of a first air pressure on the first side of the base plate that is less than a second air pressure on the second side of the base plate.

2. The apparatus in claim 1, wherein an area of a cross section of the hollow main body of each of the diaphragms is equal to a diameter of each of the through holes of the base plate.

3. The apparatus in claim 1, wherein the petaline portions are integrally formed with the hollow main body of the corresponding diaphragm.

4. The apparatus in claim 1, wherein the petaline portions are made of a flexible material.

5. A heat dissipating device for an electronic device comprising:
a fan; and
a base plate, having a first side and a second side, arranged to align with the fan, the base plate defining a plurality of through holes therein; and
a plurality of diaphragms, each diaphragm configured to receive a flow of air through a hollow main body of the diaphragm; and
a plurality of movable petaline portions extending out from an end of the diaphragm, each of the diaphragms fixably engaged in each of the through holes of the base plate, and the petaline portions of each of the diaphragms exposed on a side of the base plate away from the fan; and
wherein the diaphragms are capable of opening and closing in response to a predetermined pressure differential.

6. The heat dissipating device in claim 5, wherein an area of a cross section of the diaphragm is substantially equal to the diameter of each of the through holes of the base plate.

7. The heat dissipating device in claim 5, wherein the petaline portions are integrally formed with the corresponding diaphragm.

8. The heat dissipating device in claim 5, wherein the petaline portions are made of flexible material.

9. The heat dissipating device in claim 5, wherein the petaline portions of each of the diaphragms forms a dome-shaped protrusion when the petaline portions are in a closed position.

10. An apparatus for preventing refluence of air in an electronic device, the apparatus comprising:
a base plate, having a first side and a second side; the base plate defining a plurality of through holes therein; and
a plurality of diaphragms, each diaphragm having a hollow main body, the main body configured to receive a flow of air through the hollow main body, and output the flow of air through a plurality petaline portions extending out from the main body, wherein each of the main bodies are fixably engaged in the through holes;
wherein the diaphragms are biased closed and the petalines are configured to move away from each other to form an open position in response to a first air pressure on the first side of the base plate that is less than a second air pressure on the second side of the base plate such that a sufficient difference in air pressure will overcome the biasing force of the petaline portions.

11. The apparatus of claim 10, wherein the second side of the base plate is adjacent to a fan.
